(19) United States
(12) Patent Application Publication
(10) Pub. No.: US 2022/0045350 A1
(43) Pub. Date: Feb. 10, 2022

(54) SYSTEM AND METHOD FOR MANUFACTURING LITHIUM ION SECONDARY BATTERY

(71) Applicants: HYUNDAI MOTOR COMPANY, Seoul (KR); KIA MOTORS CORPORATION, Seoul (KR)

(72) Inventors: Sang Mok Park, Gwangju-si (KR); Yea Yeon Lee, Seoul (KR); Seung Ho Ahn, Hanam-si (KR); Yoon Ji Lee, Bucheon-si (KR)

(21) Appl. No.: 17/154,613

(22) Filed: Jan. 21, 2021

(30) Foreign Application Priority Data
Aug. 10, 2020 (KR) 10-2020-0099922

(51) Int. Cl. H01M 10/0525; H01M 10/058; H01M 10/48; H01M 4/66; H01M 4/134

(52) U.S. Cl. CPC H01M 10/0525; H01M 10/058; H01M 4/134; H01M 4/661; H01M 10/48

(57) ABSTRACT

A system for manufacturing a lithium ion secondary battery includes: an electrode assembly that includes a cathode electrode, an anode electrode, and a separator positioned between the cathode electrode and the anode electrode, and is impregnated with an electrolyte; a lithium part disposed on a surface of the electrode assembly, electrically connected to the cathode electrode or the anode electrode, and supplying lithium to the electrode assembly or receiving lithium deintercalated from the electrode assembly; and a controller allowing supply of lithium ions from the lithium part to the electrode assembly or allowing deintercalation of lithium ions from the electrode assembly.

### CROSS REFERENCE TO RELATED APPLICATION

The present application claims the benefit of priority to Korean Patent Application No. 10-2020-0099922, filed on Aug. 10, 2020 in the Korean Intellectual Property Office, the entire contents of which is incorporated herein by reference.

### TECHNICAL FIELD

The present disclosure relates to a system and a method for manufacturing a lithium ion secondary battery. More particularly, the present disclosure relates to a system and a method for manufacturing a lithium ion secondary battery, the system and method being capable of improving energy density of the lithium ion secondary battery.

### BACKGROUND

Recently, research on high energy density of secondary batteries has been performed. Si, Ge, Sn, Pb, etc. are metals capable of intercalating lithium and have a theoretical capacity of 10 times or more compared to the capacity of graphite, which is mainly used in lithium ion batteries. However, these metals have problems such as very low initial charging and discharging efficiency compared to graphite, and volume expansion, so in actual cells, graphite is used as a main component and the metals are mixed in an amount of about 10%.

In order to solve such initial efficiency problem, there is a known method of reacting separate lithium to an anode electrode before final assembly of a cell, or supplying lithium to the anode electrode after configuring a separate cell and then reconfiguring the cell with the anode electrode supplied with lithium.

However, the above-described method is difficult to apply to actual products in terms of productivity, cost, and effectiveness.

The information disclosed in the Background section above is to aid in the understanding of the background of the present disclosure, and should not be taken as acknowledgement that this information forms any part of prior art.

### SUMMARY

Accordingly, the present disclosure has been made keeping in mind the above problems occurring in the related art, and an objective of the present disclosure is to provide a system and a method for manufacturing a lithium ion secondary battery, wherein an electrode assembly for allowing passage of lithium ions through a cathode electrode and an anode electrode is provided by the use of a cathode current collector and an anode current collector each of which has a channel for allowing passage of lithium ions, the electrode assembly is impregnated with an electrolyte, and then a desired amount of lithium is supplied to the anode electrode in the electrode assembly at a desired rate through a lithium part, whereby energy density of a battery cell is improved.

In order to achieve the above objective, according to one aspect of the present disclosure, a system for manufacturing a lithium ion secondary battery includes: an electrode assembly that includes a cathode electrode, an anode electrode, and a separator positioned between the cathode electrode and the anode electrode, and is impregnated with an electrolyte; a lithium part disposed on a surface of the electrode assembly, electrically connected to the cathode electrode or the anode electrode, and supplying lithium to the electrode assembly or receiving lithium deintercalated from the electrode assembly; and a controller configured to allow supply of lithium ions from the lithium part to the electrode assembly or to allow deintercalation of lithium ions from the electrode assembly.

The lithium part may include a material that has a lower potential than the anode electrode after injection of the electrolyte.

The lithium part may include one of Li-Metal, Al—Li alloy, Li₃N, Li₃-xMxN (M=Ni, Co, Cu, 0≤x≤1.0), Li₇MnN₄, and Li₃FeN₂.

The lithium part may include a material that has a higher potential than the anode electrode after injection of the electrolyte.

The lithium part may include any one of a layered oxide type including LiMO₂ (M=Ni, Co, Mn, Al), and xLi₂MnO₃.(1-x)LiMO₂ (0<x<1, M=Ni, Mn, Co), a spinel type including LiMn₂O₄, LiNi_{0.5}Mn_{1.5}O₄, and LiMn_{1.5}Ni_{0.5}O₂, or a polyanion type including LiFePO₄, LiMnPO₄, Li₂MnSiO₄, and LiFeBO₃.

A channel for allowing passage of metal ions may be disposed in each of a cathode current collector of the cathode electrode and an anode current collector of the anode electrode.

An active material may not be coated on an outside of the cathode electrode or the anode electrode located at an outermost side of the electrode assembly.

The system may further include at least one of: a first voltage measuring part measuring a voltage between the lithium part and the anode electrode; a second voltage measuring part measuring a voltage between the cathode electrode and the anode electrode; a variable resistor arranged between the lithium part and the cathode electrode or between the lithium part and the anode electrode; a power supply part supplying power; or a monitoring part monitoring at least one of a lithium supply rate or a lithium supply amount of lithium supplied from the lithium part to the electrode assembly.

The controller may control at least one of the lithium supply amount or the lithium supply rate of lithium supplied from the lithium part to the electrode assembly on the basis of at least one of a potential magnitude relationship between the lithium part and the anode electrode, a potential magnitude relationship between the lithium part and the cathode electrode, a potential difference between the lithium part and the anode electrode, or a potential difference between the cathode electrode and the anode electrode.

When a potential of the lithium part is equal to or higher than that of the anode electrode, the controller may allow lithium ions to be supplied from the lithium part to the anode electrode through the power supply part, and control at least one of an intensity of a current, a total current amount, or a voltage supplied from the power supply part.

When a potential of the lithium part is lower than that of the anode electrode, the controller may allow lithium ions to be supplied from the lithium part to the anode electrode through the variable resistor, and control at least one of an intensity of a current, a total current amount, or a voltage supplied from the power supply part.

When the potential of the lithium part is higher than that of the anode electrode, the controller may allow lithium ions to be deintercalated from the anode electrode through the variable resistor, and control at least one of the intensity of the current, the total current amount, or the voltage supplied from the power supply part.

When the potential of the lithium part is equal to or lower than that of the anode electrode, the controller may allow lithium ions to be deintercalated from the anode electrode through the power supply part, and control at least one of the intensity of the current, the total current amount, and the voltage supplied from the power supply part.

When the potential of the lithium part is equal to or higher than that of the cathode electrode, the controller may allow lithium to be supplied to the cathode electrode through the power supply part, and control at least one of the intensity of the current, the total current amount, or the voltage supplied from the power supply part.

When the potential of the lithium part is lower than that of the cathode electrode, the controller may allow lithium to be supplied to the cathode electrode through the variable resistor, and control at least one of the intensity of the current, the total current amount, or the voltage supplied from the power supply part.

When the potential of the lithium part is higher than that of the cathode electrode, the controller may allow lithium ions to be deintercalated from the cathode electrode through the variable resistor, and control at least one of the intensity of the current, the total current amount, or the voltage supplied from the power supply part.

When the potential of the lithium part is equal to or lower than that of the cathode electrode, the controller may allow lithium ions to be deintercalated from the cathode electrode through the power supply part, and control at least one of the intensity of the current, the total current amount, or the voltage supplied from the power supply part.

The controller may allow lithium ions to be supplied from the lithium part to the anode electrode at least until a time at which lithium is deposited on a surface of the anode electrode.

The controller may allow lithium ions to be supplied from the lithium part to the cathode electrode and the anode electrode, and control lithium amounts so that a total lithium amount supplied to the anode electrode is equal to or larger than an irreversible capacity of the anode electrode, and a total lithium amount supplied to the cathode electrode is equal to or less than a maximum lithium amount that the cathode electrode can receive.

The controller may allow lithium to be deintercalated from the anode electrode and recovered to the lithium part, except for an amount corresponding to an irreversible capacity of the anode electrode of a total lithium amount supplied to the anode electrode.

An available capacity of lithium the anode electrode is capable of initially receiving may be equal to or larger than an available capacity of lithium initially deintercalated from the cathode electrode.

A cathode active material coated on the cathode electrode may include at least one of TiS₂, VSe₂, V₂S₅, Fe_{0.25}V_{0.75}S₂, Cr_{0.75}V_{0.25}S₂, NiPS₃, FePS₃, CuCo₂S₄, CuS, NbSe₃, MoS₃, Cr₃O₄, V₆O₁₃, V₂O₅, MoO₃, or Cu_{2.33}V₄O₁₁.

According to another aspect of the present disclosure, a method for manufacturing a lithium ion secondary battery includes: providing a cathode electrode; providing an anode electrode; stacking a separator between the cathode electrode and the anode electrode to form an electrode assembly; placing the electrode assembly in a battery cell casing and injecting an electrolyte; disposing a lithium part on a surface of the electrode assembly; and allowing lithium ions to be supplied from the lithium part to the electrode assembly or allowing lithium ions to be deintercalated from the electrode assembly.

The method may further include: after the allowing the lithium ions to be supplied from the lithium part to the electrode assembly or allowing the lithium ions to be deintercalated from the electrode assembly, sealing the battery case cell casing; and performing aging and formation processes.

According to the present disclosure, by minimizing the irreversible capacity of the anode electrode through pre-lithiation, it is possible to improve energy density of a battery cell.

In addition, by producing the electrode assembly, inserting the electrode assembly into the battery cell casing, and then performing a pre-lithiation process, it is possible to minimize a contact time and a contact area with air.

In addition, by supplying lithium from the outside of the electrode assembly, it is possible to freely control a supply amount of lithium.

Furthermore, by forming no perforations in the cathode electrode and the anode electrode, it is possible to minimize loss of energy density due to the formation of the perforations, and minimize non-uniform reactions due to perforation.

Furthermore, by supplying lithium to the cathode electrode through the lithium part, it is possible to allow for the use of a material that does not initially include lithium as the cathode active material.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a view schematically illustrating the overall configuration of a system for manufacturing a lithium ion secondary battery according to an exemplary embodiment of the present disclosure;

FIG. 2 is an enlarged view of part A of FIG. 1;

FIG. 3 is a view illustrating lithium ions supplied from a lithium part to an electrode assembly according to the system for manufacturing the lithium ion secondary battery according to an exemplary embodiment of the present disclosure;

FIG. 4 is a view illustrating a method for manufacturing a lithium ion secondary battery according to an exemplary embodiment of the present disclosure; and

FIG. 5 is a view illustrating the effect of the method for manufacturing the lithium ion secondary battery according to an exemplary embodiment of the present disclosure.

### DETAILED DESCRIPTION

Hereinafter, exemplary embodiments of a system and a method for manufacturing a lithium ion secondary battery according to the present disclosure will be described with reference to the drawings.

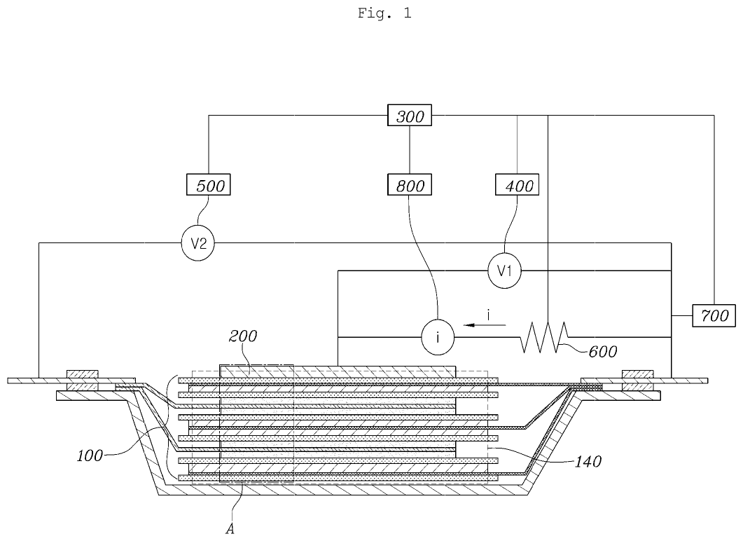

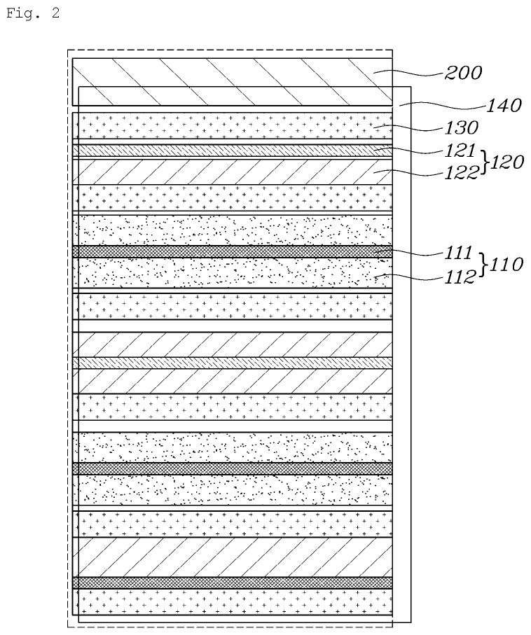

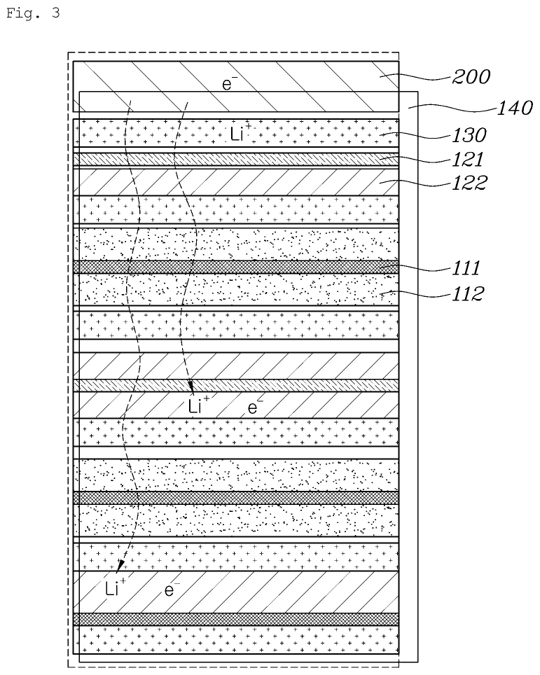

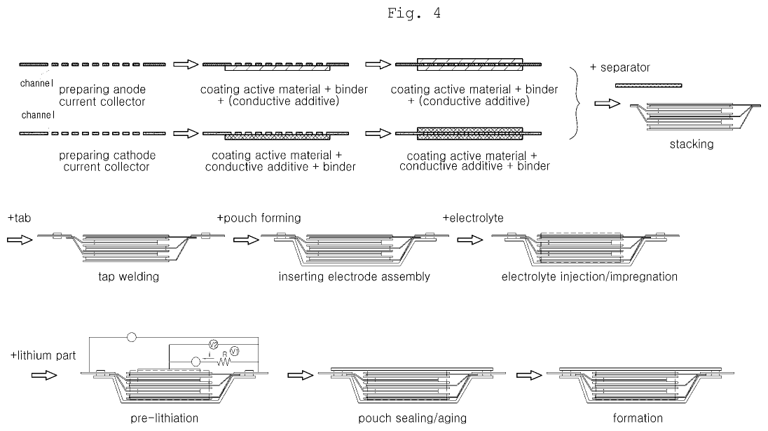

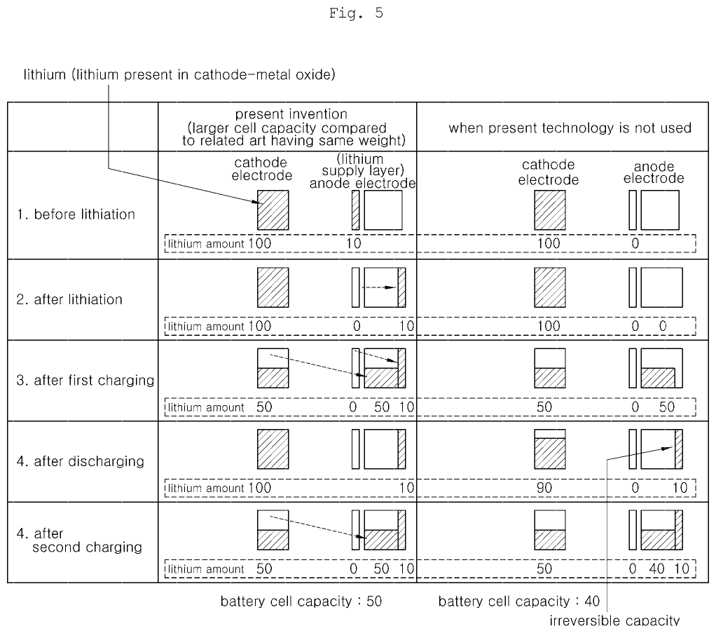

FIG. 1 is a view schematically illustrating the overall configuration of a system for manufacturing a lithium ion secondary battery according to an exemplary embodiment of the present disclosure, FIG. 2 is an enlarged view of part A of FIG. 1, and FIG. 3 is a view illustrating lithium ions supplied from a lithium part to an electrode assembly according to the system for manufacturing the lithium ion secondary battery according to an exemplary embodiment of the present disclosure. In addition, FIG. 4 is a view illustrating a method for manufacturing a lithium ion secondary battery according to an exemplary embodiment of the present disclosure, and FIG. 5 is a view illustrating the effect of the method for manufacturing the lithium ion secondary battery according to an exemplary embodiment of the present disclosure.

Referring to FIG. 1, the system for manufacturing the lithium ion secondary battery according to an embodiment of the present disclosure may include: an electrode assembly 100 including a cathode electrode 110, an anode electrode 120, and a separator 130 positioned between the cathode electrode 110 and the anode electrode 120, and impregnated with an electrolyte 140; a lithium part 200 provided on a surface of the electrode assembly 100, electrically connected to the cathode electrode 110 or the anode electrode 120, and supplying lithium to the electrode assembly 100 or receiving lithium deintercalated from the electrode assembly 100; and a controller 300 allowing supply of lithium ions from the lithium part 200 to the electrode assembly 100 or allowing deintercalation of lithium ions from the electrode assembly 100.

In addition, the system may further include at least one of: a first voltage measuring part 400 measuring a voltage between the lithium part 200 and the anode electrode 120; a second voltage measuring part 500 measuring a voltage between the cathode electrode 110 and the anode electrode 120; a variable resistor 600 provided between the lithium part 200 and the cathode electrode 110 or between the lithium part 200 and the anode electrode 120; a power supply part 700 supplying power; or a monitoring part 800 monitoring at least one of a lithium supply rate or a lithium supply amount of lithium supplied from the lithium part 200 to the electrode assembly 100. According to an embodiment, the first voltage measuring part 400 and the second voltage measuring part 500 may be voltage sensors, and the monitoring part 800 may monitor the lithium supply rate and the lithium supply amount of lithium supplied from the lithium part 200 to the electrode assembly 100, in response to a current and an accumulated current supplied from the power supply part 700, the current and the accumulated current being measured by a current measuring device. According to another exemplary embodiment, the monitoring part 800 may be a current sensor capable of measuring the current and the accumulated current supplied from the power supply part 700.

The anode electrode 120 may include an anode current collector 121 and an anode coating layer coated on the anode current collector 121. Here, a channel for allowing passage of metal ions may be formed in the anode current collector 121. According to an exemplary embodiment, the channel for the passage of the metal ions may be formed in the form of micropores. However, this is only an example, and the shape of the channel is not limited thereto as long as a channel for allowing passage of metal ions can be formed. For example, when the metal ions are lithium ions, it is preferable that the channel is formed in a size that allows passage of the lithium ions.

Meanwhile, the anode current collector 121 may be any conductor, and according to an exemplary embodiment, may be copper, aluminum, stainless steel, nickel plated steel, or the like, but is not limited thereto.

An anode active material 122 may be coated on each of opposite surfaces of the anode current collector 121. However, when the anode electrode 120 is located on the outermost side of the electrode assembly 100, according to an exemplary embodiment, the anode active material 122 may be coated on each of the opposite surfaces of the anode current collector 121, and according to another exemplary embodiment, the anode active material 122 may not be coated on the outside of the anode current collector 121.

The anode active material 122 may include a metal-based active material and a carbon-based active material. In this case, the metal-based active material may include a silicon-based active material, a tin-based active material, or a combination thereof, and the carbon-based active material is a material that includes carbon (atoms) and can electrochemically intercalate and deintercalate lithium ions, and according to an exemplary embodiment, may be a graphite active material, artificial graphite, natural graphite, a mixture of artificial graphite and natural graphite, or natural graphite coated with artificial graphite, but is not limited thereto.

The cathode electrode 110 serves to discharge lithium ions during charging of a cell and receive lithium ions during discharging of the cell.

Specifically, the cathode electrode 110 may include a cathode current collector 111 and a cathode coating layer coated on the cathode current collector 111. Here, a channel for allowing passage of metal ions may be formed in the cathode current collector 111. According to an exemplary embodiment, the channel for the passage of the metal ions may be formed in the form of micropores. However, this is only an example, and the shape of the channel is not limited thereto as long as a channel for allowing passage of metal ions can be formed. For example, when the metal ions are lithium ions, it is preferable that the channel is formed in a size that allows passage of the lithium ions.

Meanwhile, the cathode current collector 111 may be any conductor, but is preferably a conductor that is electrochemically stable within the range of use. According to an exemplary embodiment, the cathode current collector 111 may be aluminum, stainless steel, or nickel plated steel.

In addition, the cathode coating layer may include a cathode active material layer formed on the cathode current collector 111 and including the cathode active material 112, and a coating layer formed on the cathode active material layer 112 and including a conductive additive and a binder. According to an exemplary embodiment, when the cathode electrode 110 is located on the outermost side of the electrode assembly 100, the cathode active material 112 is not coated on the outside of the cathode current collector 111.

As such, according to the system for manufacturing the lithium ion secondary battery according to an exemplary embodiment of the present disclosure, rather than directly forming perforations in the cathode electrode 110 and the anode electrode 120, by forming channels for allowing passage of metal ions only in the cathode current collector 111 and the anode current collector 121, it is possible to minimize energy density loss compared to forming perforations in the entire electrode, minimize the effect on foreign substances generated during electrode perforation, and prevent the problem that the reaction inside the cell becomes non-uniform due to electrode perforation.

As illustrated in FIG. 1, the lithium part 200 may be provided on a surface of the electrode assembly 100 impregnated with the electrolyte 140, may be electrically connected to the cathode electrode 110 or the anode electrode 120, and may supply lithium to the electrode assembly 100 or receive lithium deintercalated from the electrode assembly 100.

According to an exemplary embodiment, the lithium part 200 may be a material that has a lower potential than the anode electrode 120 after injection of the electrolyte 140. For example, the lithium part 200 may be one of Li-Metal, Al—Li alloy, Li₃N, Li₃-xMxN (M=Ni, Co, Cu, 0≤x≤1.0), Li₇MnN₄, and Li₃FeN₂. However, this is only an example, and materials other than these may be applied to the lithium part 200 as long as they have a lower potential than the anode electrode 120 after injection of the electrolyte 140.

According to another exemplary embodiment, the lithium part 200 may be a material that has a higher potential than the anode electrode 120 after injection of the electrolyte 140. For example, the lithium part 200 may be one of a layered oxide type including LiMO₂ (M=Ni, Co, Mn, Al), and xLi₂MnO₃.(1-x)LiMO₂ (0<x<1, M=Ni, Mn, Co), a spinel type including LiMn₂O₄, LiNi_{0.5}Mn_{1.5}O₄, and LiMn_{1.5}Ni_{0.5}O₂, and a polyanion type including LiFePO₄, LiMnPO₄, Li₂MnSiO₄, and LiFeBO₃. However, this is only an example, and materials other than these may be applied to the lithium part 200 as long as they have a higher potential than the anode electrode 120 after injection of the electrolyte 140.

Hereinafter, in the system for manufacturing the lithium ion secondary battery according to an exemplary embodiment of the present disclosure, the supply of lithium ions from the lithium part 200 to the electrode assembly 100 and the deintercalation of lithium ions from the electrode assembly 100 will be described.

The controller 300 may allow lithium ions to be supplied from the lithium part 200 to the electrode assembly 100 or may allow lithium ions to be deintercalated from the electrode assembly 100. Here, the controller 300 may include a nonvolatile memory (not illustrated) configured to store an algorithm, which, when executed, controls operations of various components of a vehicle or data relating to software instructions that runs the algorithm, and a processor (not illustrated) (e.g., computer, microprocessor, CPU, ASIC, circuitry, logic circuits, etc.) configured to perform operations to be described below using the data stored in the memory. Here, the memory and the processor may be implemented as individual chips. Alternatively, the memory and the processor may be implemented as a single chip on which the memory and the processor are integrated. The processor may be implemented in the form of one or more processors.

Specifically, the controller 300 may control at least one of the lithium supply amount or the lithium supply rate of lithium supplied from the lithium part 200 to the electrode assembly 100 on the basis of at least one of a potential magnitude relationship between the lithium part 200 and the anode electrode 120, a potential magnitude relationship between the lithium part 200 and the cathode electrode 110, a potential difference between the lithium part 200 and the anode electrode 120, or a potential difference between the cathode electrode 110 and the anode electrode 120.

According to an exemplary embodiment, the controller 300 may allow lithium ions to be supplied from the lithium part 200 to the anode electrode 120 through the power supply part 700 when a potential of the lithium part 200 is higher than that of the anode electrode 120. At this time, the controller 300 may control at least one of an intensity of a current, a total current amount, or a voltage supplied from the power supply part 700, thereby controlling at least one of the lithium supply amount or the lithium supply rate of lithium supplied from the lithium part 200 to the anode electrode 120.

For example, when it is desired to increase the lithium supply rate of lithium supplied from the lithium part 200 to the anode electrode 120, the controller 300 may increase the intensity of the current supplied from the power supply part 700. On the contrary, when it is desired to reduce the lithium supply rate of lithium supplied from the lithium part 200 to the anode electrode 120, the controller 300 may reduce the intensity of the current supplied from the power supply part 700.

In addition, when it is desired to increase the lithium supply amount of lithium supplied from the lithium part 200 to the anode electrode 120, the controller 300 may increase the total current amount supplied from the power supply part 700.

On the contrary, when it is desired to reduce the lithium supply amount of lithium supplied from the lithium part 200 to the anode electrode 120, the controller 300 may reduce the total current amount supplied from the power supply part 700.

Here, it is preferable that an appropriate lithium amount supplied from the lithium part 200 to the anode electrode 120 is controlled in accordance with irreversible capacity and available capacity of the anode electrode 120. For example, when a total irreversible capacity of the anode electrode 120 is 20 mAh, the controller 300 may control the total current amount supplied from the power supply part 700 to 20 mAh.

In addition, when lithium is supplied from the lithium part 200 to the cathode electrode 110, it is preferable that the controller 300 controls the total current amount supplied from the power supply part 700 to be equal to or less than a maximum capacity of the cathode electrode 110.

According to another exemplary embodiment, the controller 300 may allow lithium ions to be supplied from the lithium part 200 to the anode electrode 120 through the variable resistor 600 when the potential of the lithium part 200 is equal to or lower than that of the anode electrode 120. At this time, the controller 300 may control a magnitude of the variable resistor 600 to control at least one of the intensity of the current, the total current amount, or the voltage supplied from the power supply part 700, thereby controlling at least one of the lithium supply amount or the lithium supply rate of lithium supplied from the lithium part 200 to the anode electrode 120.

For example, when it is desired to increase the lithium supply rate of lithium supplied from the lithium part 200 to the anode electrode 120, the controller 300 may increase the lithium supply rate by reducing a resistance of the variable resistor 600. On the contrary, when it is desired to reduce lithium supply rate of lithium supplied from the lithium part 200 to the anode electrode 120, the controller 300 may reduce the lithium supply rate by increasing the resistance of the variable resistor 600.

According to another exemplary embodiment, the controller 300 may allow lithium ions to be deintercalated from the anode electrode 120 and received in the lithium part 200 through the variable resistor 600 when the potential of the lithium part 200 is higher than that of the anode electrode 120. At this time, the controller 300 may control the magnitude of the variable resistor 600 to control at least one of the intensity of the current, the total current amount, or the voltage supplied from the power supply part 700, thereby controlling at least one of a lithium reception amount or a lithium reception rate of lithium deintercalated from the anode electrode 120 and received in the lithium part 200.

For example, when it is desired to increase the lithium reception rate of lithium deintercalated from the anode electrode 120 and received in the lithium part 200, the controller 300 may increase the lithium reception rate by reducing the resistance of the variable resistor 600. On the contrary, when it is desired to reduce the lithium reception rate of lithium deintercalated from the anode electrode 120 and received in the lithium part 200, the controller 300 may reduce the lithium reception rate by increasing the resistance of the variable resistor 600.

According to another exemplary embodiment, the controller 300 may allow lithium ions to be deintercalated from the anode electrode 120 through the power supply part 700 when the potential of the lithium part 200 is equal to or lower than that of the anode electrode 120. At this time, the controller 300 may control the power supply part 700 to control at least one of the intensity of the current, the total current amount, or the voltage supplied from the power supply part 700, thereby controlling at least one of the lithium reception amount or the lithium reception rate of lithium deintercalated from the anode electrode 120 and received in the lithium part 200.

For example, when it is desired to increase the lithium reception rate of lithium deintercalated from the anode electrode 120 and received in the lithium part 200, the controller 300 may increase the lithium reception rate by increasing the intensity of the current supplied from the power supply part 700. On the contrary, when it is desired to reduce the lithium reception rate of lithium deintercalated from the anode electrode 120 and received in the lithium part 200, the controller 300 may reduce the lithium reception rate by reducing the intensity of the current supplied from the power supply part 700.

Meanwhile, in a system for manufacturing a lithium ion secondary battery according to another exemplary embodiment of the present disclosure, when a cathode electrode 110 does not include lithium, lithium may be supplied to the cathode electrode 110 through a lithium part 200. At this time, a cathode active material 112 coated on the cathode electrode 110 is a material capable of receiving lithium, and may include at least one of TiS₂, VSe₂, V₂S₅, Fe_{0.25}V_{0.75}S₂, Cr_{0.75}V_{0.25}S₂, NiPS₃, FePS₃, CuCo₂S₄, CuS, NbSe₃, MoS₃, Cr₃O₄, V₆O₁₃, V₂O₅, MoO₃, or Cu_{2.33}V₄O₁₁. That is, in the system for manufacturing the lithium ion secondary battery according to the other embodiment of the present disclosure, the cathode active material 112 that does not include lithium may be used.

According to an exemplary embodiment, a controller 300 may allow lithium to be supplied to the cathode electrode 110 through the power supply part 700 when the potential of the lithium part 200 is equal to or higher than that of the cathode electrode 110. At this time, the controller 300 may control at least one of an intensity of a current, a total current amount, or a voltage supplied from the power supply part 700, thereby controlling at least one of a lithium supply amount or a lithium supply rate of lithium supplied from the lithium part 200 to the cathode electrode 110.

For example, when it is desired to increase the lithium supply rate of lithium supplied from the lithium part 200 to the cathode electrode 110, the controller 300 may increase the intensity of the current supplied from the power supply part 700. On the contrary, when it is desired to reduce the lithium supply rate of lithium supplied from the lithium part 200 to the cathode electrode 110, the controller 300 may reduce the intensity of the current supplied from the power supply part 700.

In addition, when it is desired to increase the lithium supply amount of lithium supplied from the lithium part 200 to the cathode electrode 110, the controller 300 may increase the total current amount supplied from the power supply part 700.

On the contrary, when it is desired to reduce the lithium supply amount of lithium supplied from the lithium part 200 to the cathode electrode 110, the controller 300 may reduce the total current amount supplied from the power supply part 700.

According to another exemplary embodiment, the controller 300 may allow lithium ions to be supplied from the lithium part 200 to the cathode electrode 110 through a variable resistor 600 when the potential of the lithium part 200 is lower than that of the cathode electrode 110. At this time, the controller 300 may control a magnitude of the variable resistor 600 to control at least one of the intensity of the current, the total current amount, or the voltage supplied from the power supply part 700, thereby controlling at least one of the lithium supply amount or the lithium supply rate of lithium supplied from the lithium part 200 to the cathode electrode 110.

For example, when it is desired to increase the lithium supply rate of lithium supplied from the lithium part 200 to the cathode electrode 110, the controller 300 may increase the lithium supply rate by reducing a resistance of the variable resistor 600. On the contrary, when it is desired to reduce the lithium supply rate of lithium supplied from the lithium part 200 to the cathode electrode 110, the controller 300 may reduce the lithium supply rate by increasing the resistance of the variable resistor 600.

Meanwhile, in the system for manufacturing the lithium ion secondary battery according to an exemplary embodiment of the present disclosure, when the cathode electrode 110 has high irreversible capacity, lithium ions may be deintercalated from the cathode electrode 110 and received in the lithium part 200.

According to another exemplary embodiment, the controller 300 may allow lithium ions to be deintercalated from the cathode electrode 110 and received in the lithium part 200 through the variable resistor 600 when the potential of the lithium part 200 is higher than that of the cathode electrode 110. At this time, the controller 300 may control the magnitude of the variable resistor 600 to control at least one of the intensity of the current, the total current amount, or the voltage supplied from the power supply part 700, thereby controlling at least one of a lithium reception amount or a lithium reception rate of lithium deintercalated from the cathode electrode 110 and received in the lithium part 200.

For example, when it is desired to increase the lithium reception rate of lithium deintercalated from the cathode electrode 110 and received in the lithium part 200, the controller 300 may increase the lithium reception rate by reducing the resistance of the variable resistor 600. On the contrary, when it is desired to reduce the lithium reception rate of lithium deintercalated from the cathode electrode 110 and received in the lithium part 200, the controller 300 may reduce the lithium reception rate by increasing the resistance of the variable resistor 600.

According to another exemplary embodiment, the controller 300 may allow lithium ions to be deintercalated from the cathode electrode 110 through the power supply part 700 when the potential of the lithium part 200 is equal to or lower than that of the cathode electrode 110. At this time, the controller 300 may control the power supply part 700 to control at least one of the intensity of the current, the total current amount, or the voltage supplied from the power supply part 700, thereby controlling at least one of the lithium reception amount or the lithium reception rate of lithium deintercalated from the cathode electrode 110 and received in the lithium part 200.

For example, when it is desired to increase the lithium reception rate of lithium deintercalated from the cathode electrode and received in the lithium part 200, the controller 300 may increase the intensity of the current supplied from the power supply part 700. On the contrary, when it is desired to reduce the lithium reception rate of lithium deintercalated from the cathode electrode 110 and received in the lithium part 200, the controller 300 may reduce the intensity of the current supplied from the power supply part 700.

In addition, when it is desired to increase the lithium reception amount of lithium deintercalated from the cathode electrode 110 and received in the lithium part 200, the controller 300 may increase the total current amount supplied from the power supply part 700. On the contrary, when it is desired to reduce the lithium reception amount of lithium deintercalated from the cathode electrode 110 and received in the lithium part 200, the controller 300 may reduce the total current amount supplied from the power supply part 700.

Meanwhile, according to the above-described method, the controller 300 may allow lithium ions to be supplied from the lithium part 200 to the anode electrode 120 at least until the time at which lithium is deposited on the surface of the anode electrode 120. According to an exemplary embodiment, the controller 300 may allow lithium ions to be supplied from the lithium part 200 to the anode electrode 120 even after the time at which lithium is deposited on the surface of the anode electrode 120.

As such, according to the present disclosure, by allowing by the controller 300 lithium ions to be supplied from the lithium part 200 to the anode electrode 120 at least until the time at which lithium is deposited on the surface of the anode electrode 120, the same effect as using a thin-film lithium-coated anode electrode 120 can be obtained.

Meanwhile, the controller 300 may allow lithium ions to be supplied from the lithium part 200 to the cathode electrode 110 and the anode electrode 120 as described above, and control lithium amounts so that a total lithium amount supplied to the anode electrode 120 may be equal to or larger than an irreversible capacity of the anode electrode 120, and a total lithium amount supplied to the cathode electrode 110 may be equal to or less than a maximum lithium amount that the cathode electrode 110 can receive. Such an irreversible capacity and a maximum lithium amount of an electrode may be predetermined values.

For example, as illustrated in FIG. 5, when the irreversible capacity of the anode electrode 120 is 10%, the total lithium amount supplied from the lithium part 200 to the anode electrode 120 is preferably equal to or larger than 10.

In addition, on the basis of the above-described method, the controller 300 may allow lithium to be deintercalated from the anode electrode 120 and recovered to the lithium part 200, except for an amount corresponding to the irreversible capacity of the anode electrode 120 of the total lithium amount supplied to the anode electrode 120. For example, referring to FIG. 5, lithium may be deintercalated from the anode electrode 120 and recovered to the lithium part 200, except for an amount corresponding to the irreversible capacity of 10% of the anode electrode 120 of the total lithium amount supplied to the anode electrode 120.

Meanwhile, in the system for manufacturing the lithium ion secondary battery according to an exemplary embodiment of the present disclosure, it is preferable that an available capacity of lithium the anode electrode 120 is capable of initially receiving is equal to or larger than an available capacity of lithium initially deintercalated from the cathode electrode 110 after lithium is supplied to the cathode electrode 110.

FIG. 4 is a view illustrating a method for manufacturing a lithium ion secondary battery according to an exemplary embodiment of the present disclosure. Referring to FIG. 4, the method for manufacturing the lithium ion secondary battery according to the embodiment of the present disclosure may include: preparing a cathode electrode 110; preparing an anode electrode 120; stacking a separator 130 between the cathode electrode 110 and the anode electrode 120 to form an electrode assembly 100; placing the electrode assembly 100 in a battery cell casing and injecting an electrolyte 140; providing a lithium part 200 on a surface of the electrode assembly 100; and allowing lithium ions to be supplied from the lithium part 200 to the electrode assembly 100 or allowing lithium ions to be deintercalated from the electrode assembly 100.

In addition, the method may further include: after the allowing the lithium ions to be supplied from the lithium part 200 to the electrode assembly 100 or allowing the lithium ions to be deintercalated from the electrode assembly 100, sealing the battery case cell casing; and performing aging and formation processes.

Substantial technical details in each step of the method for manufacturing the lithium ion secondary battery according to the embodiment of the present disclosure remain the same as those in the system for manufacturing the lithium ion secondary battery according to the embodiment of the present disclosure described above, and thus a description thereof will be omitted.

Meanwhile, the system and method for manufacturing the lithium ion secondary battery according to the embodiments of the present disclosure has the following effects.

First, according to some exemplary embodiments of the present disclosure, by minimizing the irreversible capacity of the anode electrode 120 through pre-lithiation, it is possible to improve energy density of a battery cell. Specifically, referring to FIG. 5, a lithium amount included in the cathode electrode 110 is 100, and a lithium amount of 50 may be initially stored in the anode electrode 120 during charging. When the anode active material 122 itself has an irreversible capacity of 10% at the time of initial charging and discharging, a lithium amount corresponding to the irreversible capacity at the time of initial charging and discharging of the anode active material 122 itself may be supplied to the anode electrode 120 through the lithium part 200, whereby it is possible to improve the energy density of the battery cell by the added lithium amount.

In addition, by producing the electrode assembly 100, inserting the electrode assembly 100 into the battery cell casing, and then performing a pre-lithiation process, it is possible to minimize a contact time and a contact area with air.

In addition, by supplying lithium from the outside of the electrode assembly 100, it is possible to freely control a supply amount of lithium.

Furthermore, by forming no perforations in the cathode electrode 110 and the anode electrode 120, it is possible to minimize loss of energy density due to the formation of the perforations, and minimize non-uniform reactions due to perforation.

Furthermore, by supplying lithium to the cathode electrode 110 through the lithium part 200, it is possible to allow for the use of a material that does not initially include lithium as the cathode active material 112.

Although the exemplary embodiments of the present disclosure have been described for illustrative purposes, those skilled in the art will appreciate that various modifications, additions and substitutions are possible, without departing from the scope and spirit of the disclosure as disclosed in the accompanying claims.

What is claimed is:

1. A system for manufacturing a lithium ion secondary battery, the system comprising:
an electrode assembly including a cathode electrode, an anode electrode, and a separator positioned between the cathode electrode and the anode electrode, the electrode assembly being impregnated with an electrolyte;
a lithium part disposed on a surface of the electrode assembly, electrically connected to the cathode electrode or the anode electrode, and supplying lithium to the electrode assembly or receiving lithium deintercalated from the electrode assembly; and
a controller configured to allow supply of lithium ions from the lithium part to the electrode assembly or to allow deintercalation of lithium ions from the electrode assembly.

2. The system of claim 1, wherein the lithium part includes a material that has a lower potential than the anode electrode after injection of the electrolyte.

3. The system of claim 2, wherein the lithium part includes any one of Li-Metal, Al—Li alloy, Li₃N, Li₃-xMxN (M=Ni, Co, Cu, 0≤x≤1.0), Li₇MnN₄, or Li₃FeN₂.

4. The system of claim 1, wherein the lithium part includes a material that has a higher potential than the anode electrode after injection of the electrolyte.

5. The system of claim 1, wherein a channel for allowing passage of metal ions is disposed in each of a cathode current collector of the cathode electrode and an anode current collector of the anode electrode.

6. The system of claim 1, wherein an active material is not coated on an outside of the cathode electrode or the anode electrode located at an outermost side of the electrode assembly.

7. The system of claim 1, further comprising at least one of:
a first voltage measuring part measuring a voltage between the lithium part and the anode electrode;
a second voltage measuring part measuring a voltage between the cathode electrode and the anode electrode;
a variable resistor arranged between the lithium part and the cathode electrode or between the lithium part and the anode electrode;
a power supply part supplying power; or
a monitoring part monitoring at least one of a lithium supply rate or a lithium supply amount of lithium supplied from the lithium part to the electrode assembly.

8. The system of claim 7, wherein the controller controls at least one of the lithium supply amount or the lithium supply rate of lithium supplied from the lithium part to the electrode assembly based on at least one of a potential magnitude relationship between the lithium part and the anode electrode, a potential magnitude relationship between the lithium part and the cathode electrode, a potential difference between the lithium part and the anode electrode, or a potential difference between the cathode electrode and the anode electrode.

9. The system of claim 8, wherein when a potential of the lithium part is equal to or higher than that of the anode electrode, the controller is further configured to allow lithium ions to be supplied from the lithium part to the anode electrode through the power supply part, and to control at least one of an intensity of a current, a total current amount, or a voltage supplied from the power supply part.

10. The system of claim 8, wherein when a potential of the lithium part is lower than that of the anode electrode, the controller is further configured to allow lithium ions to be supplied from the lithium part to the anode electrode through the variable resistor, and to control at least one of an intensity of a current, a total current amount, or a voltage supplied from the power supply part.

11. The system of claim 10, wherein when the potential of the lithium part is higher than that of the anode electrode, the controller is further configured to allow lithium ions to be deintercalated from the anode electrode through the variable resistor, and to control at least one of the intensity of the current, the total current amount, or the voltage supplied from the power supply part.

12. The system of claim 10, wherein when the potential of the lithium part is equal to or lower than that of the anode electrode, the controller is further configured to allow lithium ions to be deintercalated from the anode electrode through the power supply part, and to control at least one of the intensity of the current, the total current amount, or the voltage supplied from the power supply part.

13. The system of claim 10, wherein when the potential of the lithium part is equal to or higher than that of the cathode electrode, the controller is further configured to allow lithium to be supplied to the cathode electrode through the power supply part, and to control at least one of the intensity of the current, the total current amount, or the voltage supplied from the power supply part.

14. The system of claim 10, wherein when the potential of the lithium part is lower than that of the cathode electrode, the controller is further configured to allow lithium to be supplied to the cathode electrode through the variable resistor, and to control at least one of the intensity of the current, the total current amount, or the voltage supplied from the power supply part.

15. The system of claim 10, wherein when the potential of the lithium part is higher than that of the cathode electrode, the controller is further configured to allow lithium ions to be deintercalated from the cathode electrode through the variable resistor, and to control at least one of the intensity of the current, the total current amount, or the voltage supplied from the power supply part.

16. The system of claim 10, wherein when the potential of the lithium part is equal to or lower than that of the cathode electrode, the controller is further configured to allow lithium ions to be deintercalated from the cathode electrode through the power supply part, and to control at least one of the intensity of the current, the total current amount, or the voltage supplied from the power supply part.

17. The system of claim 1, wherein the controller is further configured to allow lithium ions to be supplied from the lithium part to the anode electrode at least until a time at which lithium is deposited on a surface of the anode electrode.

18. The system of claim 1, wherein the controller is further configured to allow lithium ions to be supplied from the lithium part to the cathode electrode and the anode electrode, and to control lithium amounts so that a total lithium amount supplied to the anode electrode is equal to or larger than an irreversible capacity of the anode electrode, and a total lithium amount supplied to the cathode electrode is equal to or less than a maximum lithium amount that the cathode electrode can receive.

19. The system of claim 1, wherein the controller is further configured to allow lithium to be deintercalated from the anode electrode and recovered to the lithium part, except for an amount corresponding to an irreversible capacity of the anode electrode of a total lithium amount supplied to the anode electrode.

20. A method for manufacturing a lithium ion secondary battery, the method comprising:
preparing a cathode electrode;
preparing an anode electrode;
stacking a separator between the cathode electrode and the anode electrode to form an electrode assembly;
placing the electrode assembly in a battery cell casing and injecting an electrolyte;
disposing a lithium part on a surface of the electrode assembly; and
allowing lithium ions to be supplied from the lithium part to the electrode assembly or allowing lithium ions to be deintercalated from the electrode assembly.
